(19) United States
(12) Patent Application Publication
(10) Pub. No.: US 2025/0248100 A1
(43) Pub. Date: Jul. 31, 2025

(54) VARIABLE STACK NANOSHEET DEVICES AND METHODS FOR MAKING THE SAME

(71) Applicant: QUALCOMM Incorporated, San Diego, CA (US)

(72) Inventors: Yan SUN, San Diego, CA (US); Shreesh NARASIMHA, Charlotte, NC (US)

(21) Appl. No.: 18/428,984

(22) Filed: Jan. 31, 2024

(51) Int. Cl. H01L 29/417; H01L 27/088; H01L 29/06; H01L 29/40; H01L 29/423; H01L 29/775; H01L 29/786

(52) U.S. Cl. CPC H10D 64/254; H10D 30/43; H10D 30/6735; H10D 30/6757; H10D 62/121; H10D 64/01; H10D 84/83

(57) ABSTRACT

A field effect transistor (FET) structure and method for making the same is disclosed. In an aspect, a method of fabricating a semiconductor structure comprises providing a FET structure disposed above a substrate, the FET structure comprising a vertical metal gate structure disposed between a pair of source/drain (S/D) epitaxial (EPI) structures and having a set of vertically-stacked, horizontal nanosheets extending through the vertical metal gate structure in the first horizontal direction to electrically connect the S/D EPI structures to each other. The method further comprises removing the substrate, removing the portion of vertical metal gate structure below the bottom-most nanosheet, removing at least enough of the bottom-most nanosheet to sever the its electrical conducting path between the S/D EPI structures, and filling the void created by the removed gate metal and nanosheet with a dielectric material that also covers the bottom surfaces of the S/D EPI structures.

### BACKGROUND OF THE DISCLOSURE

### 1. Field of the Disclosure

This disclosure relates generally to semiconductor wafer process, and more specifically to variable stack nanosheet gate-all-around (GAA) field effect transistor (FET) structures and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a method of fabricating a semiconductor structure includes providing a field effect transistor (FET) structure disposed above a substrate, the FET structure comprising a vertical metal gate structure extending in a first horizontal direction and being disposed between a first source/drain (S/D) epitaxial (EPI) structure and a second S/D EPI structure set apart in a second horizontal direction, the vertical metal gate structure comprising a channel structure, the channel structure comprising a plurality of vertically-stacked, horizontal nanosheets, each nanosheet providing an electrical conducting path from the first S/D EPI structure to the second S/D EPI structure, and a gate dielectric material disposed between the vertical metal gate structure and each of the plurality of vertically-stacked, horizontal nanosheets; removing the substrate below a bottom surface of the FET structure; removing a portion of vertical metal gate structure and gate dielectric material below a bottom-most nanosheet of the vertically-stacked, horizontal nanosheets; and removing at least a portion of the bottom-most nanosheet of the vertically-stacked, horizontal nanosheets sufficient to sever its electrical conducting path from the first S/D EPI structure and the second S/D EPI structure.

In an aspect, a semiconductor structure includes a substrate; and at least one FET structure disposed above the substrate, each FET structure comprising: a vertical metal gate structure extending in a first horizontal direction and being disposed between a first S/D EPI structure and a second S/D EPI structure set apart in a second horizontal direction, the vertical metal gate structure comprising a channel structure, the channel structure comprising a plurality of vertically-stacked, horizontal nanosheets; a gate dielectric material disposed between the vertical metal gate structure and each of the plurality of vertically-stacked, horizontal nanosheets; and a backside insulating layer disposed below the vertical metal gate structure, the first S/D EPI structure and the second S/D EPI structure, wherein at least some of the vertically-stacked, horizontal nanosheets farthest from the backside insulating layer provide an electrical conducting path between the first S/D EPI structure to the second S/D EPI structure in the second horizontal direction through the vertical metal gate structure, and wherein at least one of the vertically-stacked, horizontal nanosheets closest to the backside insulating layer does not provide an electrical conducting path between the first S/D EPI structure and the second S/D EPI structure.

In an aspect, a semiconductor structure includes a plurality of FET structures extending in a first horizontal direction and set apart in a second horizontal direction, wherein each FET structure comprises: a vertical metal gate structure extending in the first horizontal direction and being disposed between a first S/D EPI structure and a second S/D EPI structure set apart in the second horizontal direction, the vertical metal gate structure comprising a channel structure, the channel structure comprising a plurality of vertically-stacked, horizontal nanosheets; a gate dielectric material disposed between the vertical metal gate structure and each of the plurality of vertically-stacked, horizontal nanosheets, at least one frontside dielectric layer disposed above the plurality of FET structures; and a backside insulating structure disposed below the plurality of FET structures, wherein for a first FET structure of the plurality of FET structures, the plurality of vertically-stacked, horizontal nanosheets comprises N nanosheets and for a second FET structure of the plurality of FET structures, the plurality of vertically-stacked, horizontal nanosheets comprises N−1 nanosheets having vertical positions that correspond with the N−1 nanosheets of the first FET structure that are closest to the at least one frontside dielectric layer.

In an aspect, a semiconductor structure includes a plurality of FET structures, each FET structure comprising a vertical metal gate structure extending in a first horizontal direction and having a first portion disposed between a first S/D EPI structure and a second S/D EPI structure set apart in a second horizontal direction, the vertical metal gate structure comprising a channel structure, the channel structure comprising a plurality of vertically-stacked, horizontal nanosheets, wherein for a first subset of the plurality of FET structures, the plurality of vertically-stacked, horizontal nanosheets comprises N nanosheets, and for a second subset of the plurality of FET structures, the plurality of vertically-stacked, horizontal nanosheets comprises N−1 nanosheets, wherein the bottom-most nanosheet of FET structures in the first subset of the plurality of FET structures is below the bottom-most nanosheet of FET structures in the second subset of the plurality of FET structures.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1A is a plan view of a conventional semiconductor structure.

FIG. 1B is a cross-sectional view of the conventional semiconductor structure.

FIG. 1C is a simplified cross-sectional view of the conventional semiconductor structure.

FIG. 1D is a cross-sectional view of the conventional semiconductor structure that has been modified using a conventional method to reduce the nanosheet count.

FIGS. 2A through 2D are cross-sectional views showing steps of a process to create a semiconductor structure with a reduced nanosheet count by backside nanosheet removal, according to aspects of the disclosure.

FIG. 3 is a flowchart showing a portion of a simplified wafer process for fabricating a semiconductor structure with a reduced nanosheet count by backside nanosheet removal, according to aspects of the disclosure.

FIG. 4 is a is a plan view of a standard cell based circuit that utilizes cells with different nanosheet counts, according to aspects of the disclosure.

FIG. 5 is a plan view of a static random access memory (SRAM) cell that utilizes cells with different nanosheet counts, according to aspects of the disclosure.

FIG. 6 is a flowchart of an example process associated with a semiconductor structure with a reduced nanosheet count by backside nanosheet removal, according to aspects of the disclosure.

FIG. 7 illustrates a mobile device in accordance with some examples of the disclosure.

FIG. 8 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

A field effect transistor (FET) structure and method for making the same is disclosed. In an aspect, a method of fabricating a semiconductor structure comprises providing a field effect transistor (FET) structure disposed above a substrate, the FET structure comprising a vertical metal gate structure disposed between a pair of source/drain (S/D) epitaxial (EPI) structures and having a set of vertically-stacked, horizontal nanosheets extending through the vertical metal gate structure in the first horizontal direction to electrically connect the S/D EPI structures to each other. The method further comprises removing the substrate, removing the portion of vertical metal gate structure below the bottom-most nanosheet, removing the bottom-most nanosheet, and filling the void created by the removed portion of the gate metal and nanosheet with a dielectric material that also covers the bottom surfaces of the S/D EPI structures.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Particular aspects of the subject matter described in this disclosure can be implemented to realize one or more of the following potential advantages. Because the recessed S/D EPI structures extend below the gate structures, backside contacts are far enough away from the gate structures that there is less chance that a process error (e.g., an etch process that etched too deep, a lithography process that was not completely aligned to the wafer, etc.) will cause the backside contact to short circuit with the gate. Also, since the contact does not have to fit solely within the space between adjacent gates, a backside contact can be made with a larger surface area, which reduces contact resistance.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

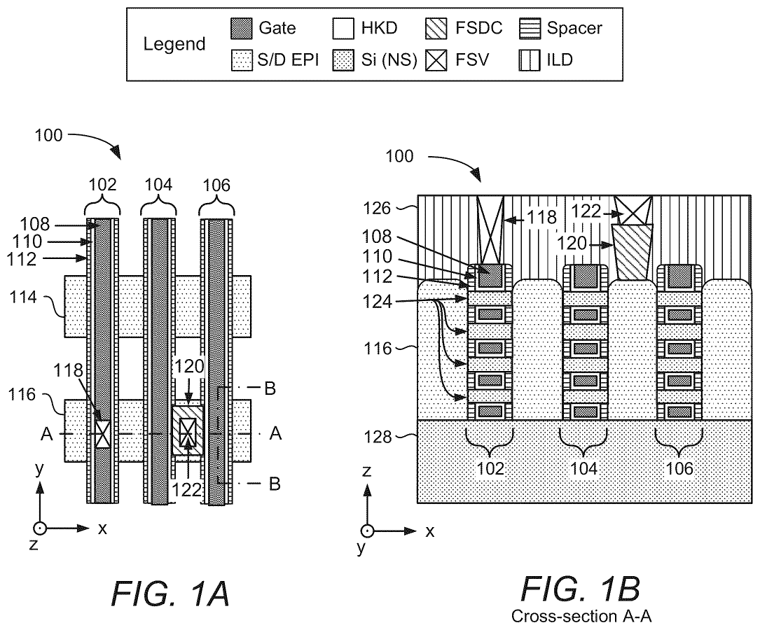

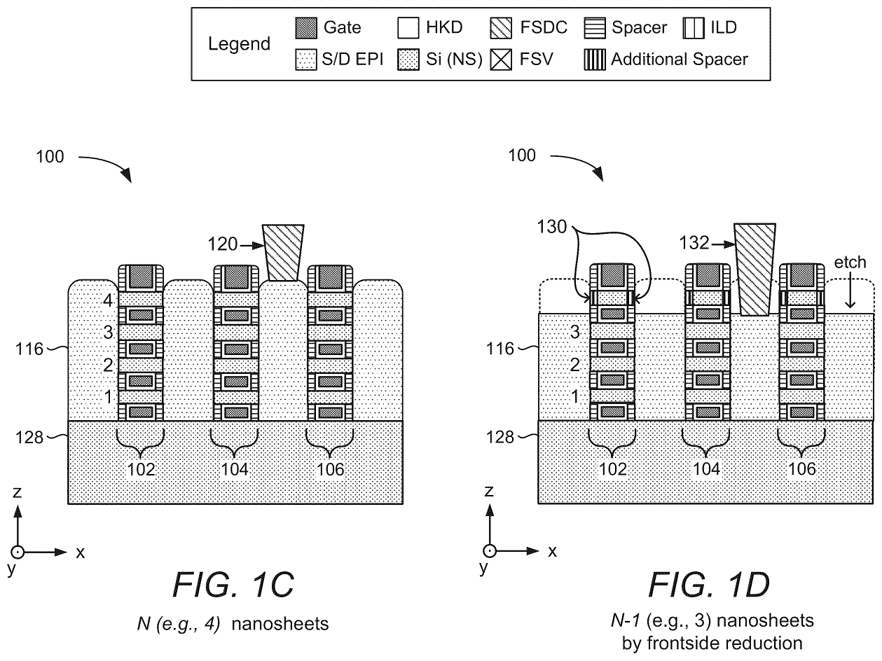

FIG. 1A is a plan view of a portion of a semiconductor structure 100 of a conventional integrated circuit (IC) device. In some aspects, FIG. 1A merely shows some elements of the semiconductor structure 100 for illustration purposes, and other elements above and/or below the elements shown in FIG. 1A may be disposed but not shown in FIG. 1A. As shown in FIG. 1A, the semiconductor structure 100 includes gate stacks 102, 104, and 106 spaced along a first direction (e.g., the x direction) and having a length along a second direction (e.g., the y direction). As used herein, the term “gate stack” refers to a structure that includes a metal gate (MG) 108 and which may also include dielectric material 110, spacer 112, and other structural components. As used herein, the terms “gate” and “gate stack” are synonymous unless specifically indicated as otherwise. The semiconductor structure 100 also includes a first region of source/drain (S/D) epitaxial (EPI) structures 114 between the gate stacks and a second region of S/D EPI structures 116 between the gate stacks. The semiconductor structure 100 also includes a first frontside via (FSV) 118, which may also be referred to a gate via (Vg). The semiconductor structure 100 also include a frontside S/D diffusion contact (FSDC) 120, and a second FSV 122, which may also be referred to as diffusion via (Vd).

FIG. 1B is a first cross-sectional view of the semiconductor structure 100 along cut-line A-A. As can be seen in FIG. 1B, each gate cross-section includes the MG 108 through which one or more silicon nanosheet channels 124 extend, insulated from the MG 108 by the dielectric material 110 and insulated from the EPI structures by the spacer 112. As shown in FIG. 1B, a frontside inter-layer dielectric (ILD) stack 126, comprising one or more layers of ILD, covers the tops of the gate stacks and EPI regions. It is through this stack 126 that the first FSV 118, the FSDC 120, and the second FSV 122 extend. As shown in FIG. 1B, the gate stacks and S/D EPI structures are disposed on a top surface of a substrate 128, which may be silicon or another material.

FIG. 1C is a simplified cross-sectional view of the semiconductor structure 100 along cut line A-A, showing unmodified gate stacks with N=4 nanosheet channels (which may also be referred to herein as ribbons or nanosheets). The nanosheet stack count directly impacts the power consumption, e.g., due to effective capacitance (C_{EFF}) and channel parameter (W_{EFF}). Conventional GAA devices have a fixed number of channels, even for portions of the circuit that might benefit from having fewer channels. This limits how much power can be reduced through design. One solution is to create the standard nanosheet stack using the standard wafer process, then modify the nanosheet stack after the fact.

FIG. 1D is a cross-sectional view of the semiconductor structure 100 after an etch step that removes the top portions of the S/D EPI structures 116 and a deposition step that creates additional spacers 130 to electrically isolate the top nanosheet. Because the resulting structure has only three nanosheet channels (N=3), its power consumption of the modified structure shown in FIG. 1D will be lower than the power consumption of the unmodified structure shown in FIG. 1C. However, this frontside modification requires additional modifications, such as the use of taller FSDC 132, which requires a deeper etch depth. If only some portions of the total circuit are modified to reduce the stack count but other portions of the total circuit are not modified, then the contact etch needs to accommodate both N and N−1 stack regions, which makes the process control more challenging.

To address these issues, techniques for variable-stack nanosheet devices via backside nanosheet removal are herein presented. In some aspects, a conventional frontside process is followed by a process to remove nanosheets from the back side of the device rather than the front side of the device. These techniques are compatible with backside power distribution network (BSPDN) designs, and require no modification of front-end-of-line (FEOL) or middle-of-line (MOL) wafer process flows—e.g., normal-height FSDCs may be used.

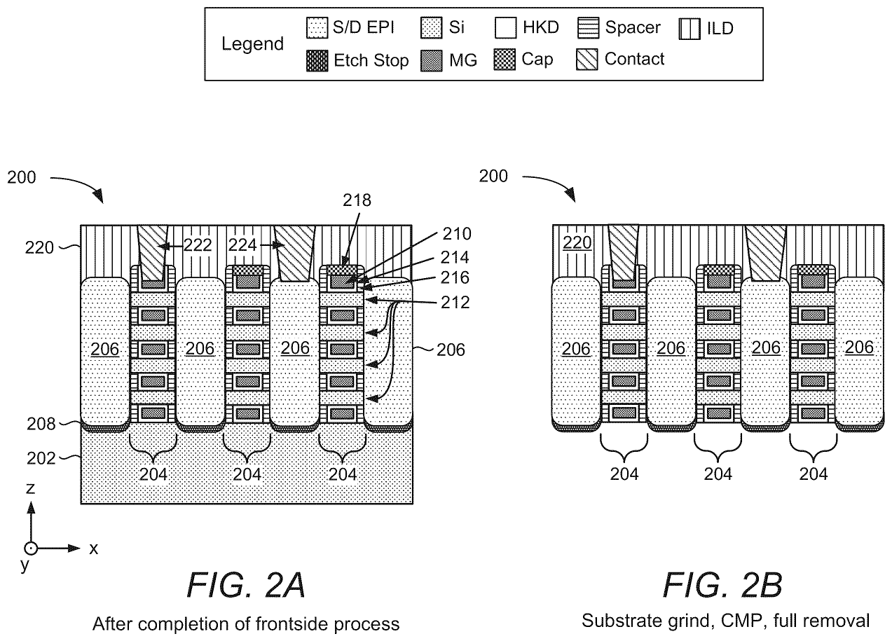

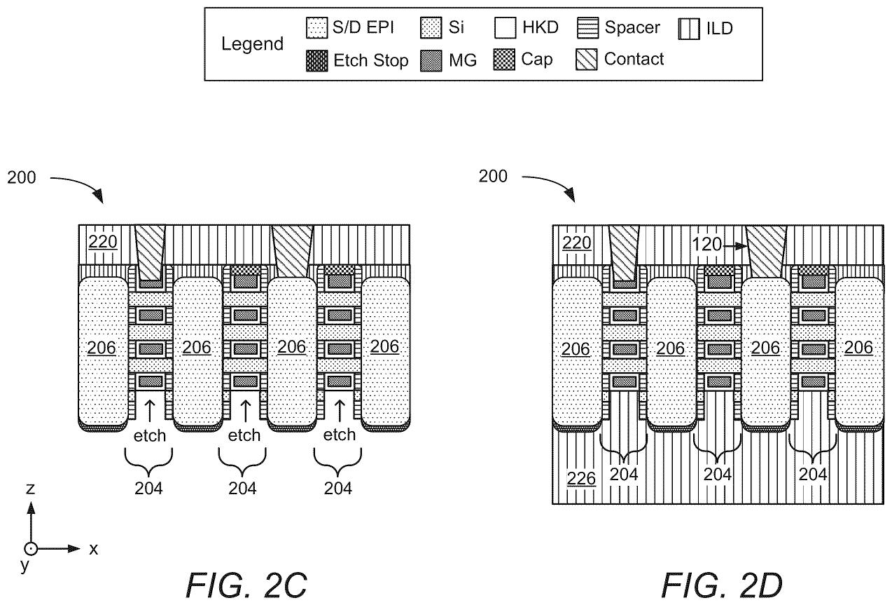

FIGS. 2A through 2D are cross-sectional views showing steps of a process to create a semiconductor structure with a reduced nanosheet count by backside nanosheet removal, according to aspects of the disclosure.

FIG. 2A shows a semiconductor structure 200 after completion of a frontside process. As shown in FIG. 2A, the semiconductor structure 200 includes a silicon substrate 202 upon which have been built gate stacks 204 spaced along a first direction (e.g., the x direction) and having a length along a second direction (e.g., the y direction). The gate stacks 204 separate S/D EPI regions 206. Etch stop structures 208 separate the S/D EPI regions 206 from the substrate 202. As shown in FIG. 2A, each gate stack 204 includes a vertical metal gate structure 210 with multiple nanosheet channels 212 connecting S/D EPI regions on either side of the gate stack through the vertical metal gate structure 210. The nanosheet channels 212 are electrically isolated from the vertical metal gate structure 210 by a gate dielectric structure 214, which may be a high-K dielectric (HKD) structure, and the vertical metal gate structure 210 is electrically isolated from the S/D EPI regions 206 by a spacer material 216. As used herein, the term “high-K” refers to a material that has a K value that is higher (e.g., between 4× and 6× times higher, between 3× and 7× times higher, between 2× and 8× times higher, etc.) than silicon dioxide (SiO₂), which has a K value of 3.9. Examples of high-K materials include, but are not limited to, hafnium oxide (HfOₓ), which has a K value of approximately 15 to 25. A dielectric cap structure 218 is disposed on the top surface of the vertical metal gate structure 210. An ILD layer 220 covers the gate stacks 204 and S/D EPI regions 206. In the example shown in FIG. 2A, the semiconductor structure 200 includes a gate contact 222 and a S/D contact 224.

FIG. 2B shows the semiconductor structure 200 after a process for removing the substrate 202. This process may include attaching the device to a carrier wafer, performing a substrate grind, performing a CMP process, and/or other processes to fully remove the substrate 202.

FIG. 2C shows the semiconductor structure 200 after an etch step that removes the bottom layer of the gate dielectric structure 214, the portion of the vertical metal gate structure 210 below the bottom-most nanosheet channel, and the bottom-most nanosheet channel from each of the gate stacks 204.

FIG. 2D shows the semiconductor structure 200 after deposition of a backside ILD layer 226. Example materials that may be used for the backside ILD layer 226 include, but are not limited to, silicon oxide (SiO₂), silicon nitride (Si₃N₄), and silicon carbon oxynitride (SiCON). The resulting gate stacks 204 will have one less nanosheet. In the example shown in FIGS. 2A-2D, all gate stacks 204 are subjected to the backside nanosheet removal process, but it will be understood that in some aspects, only selected gate stacks or parts of gate stacks will have nanosheets removed in this manner.

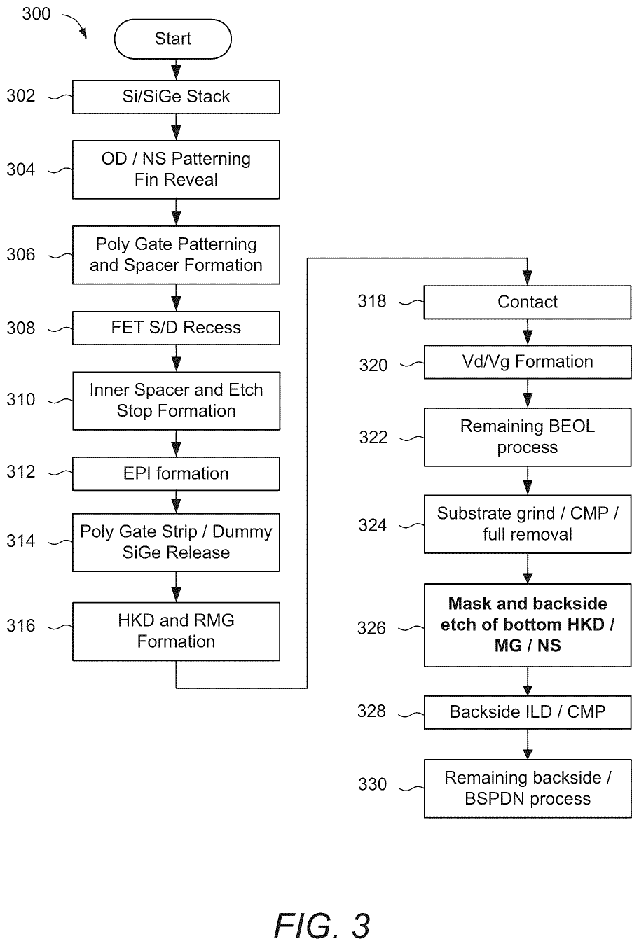

FIG. 3 is a flowchart showing a portion of a simplified wafer process for fabricating a semiconductor structure with a reduced nanosheet count by backside nanosheet removal, according to aspects of the disclosure. As shown in FIG. 3, the process 300 may include forming the Si/SiGe stack (block 302), performing oxide diffusion/nanosheet patterning and fin reveal (block 304), polysilicon gate patterning (block 306), creating FET S/D recesses (block 308), deposition of a spacer and deposition of an etch stop structure (block 310), formation of S/D EPI structures (block 312), performing a poly gate strip and dummy SiGe release process (block 314) and a high-K dielectric (HKD) and metal gate (MG) process (block 316), formation of contacts (block 318), and Vd/Vg formation (block 320), followed by the remaining steps of the back-end-of-line (BEOL) process (block 322), e.g., resulting in the semiconductor structure 200 as shown in FIG. 2A.

As further shown in FIG. 3, the process 300 may include a substrate grind process, a CMP process, and full substrate removal process (block 324), e.g., resulting in the semiconductor structure 200 as shown in FIG. 2B.

As further shown in FIG. 3, the process 300 may include mask and etch steps to remove the bottom HKD layer, MG structure, and nanosheet (NS) structure from a gate stack (block 326), e.g., resulting in the semiconductor structure 200 as shown in FIG. 2C.

As further shown in FIG. 3, the process 300 may include a backside ILD deposition followed by chemical/mechanical polishing (CMP) (block 328), and the remaining steps of the backside and/or backside power distribution network (BSPDN) process (block 330), e.g., resulting in the semiconductor structure 200 as shown in FIG. 2D.

In the examples above, only one nanosheet channel is removed from each gate stack 204, but in some aspects, more than one nanosheet channel may be removed. In some aspects, a standard cell library may include cells, each cell comprising a group of transistor and interconnect structures that provides a logic or storage function; different cells may have different nanosheet counts, and one cell may include transistors having different nanosheet counts from each other. For example, a standard cell library may have a logic cell with N nanosheets, the same logic cell with N−1 nanosheets, the same logic cell with N−2 nanosheets, etc. Likewise, a single standard cell may have a first portion with N nanosheets and a second portion with less than N nanosheets.

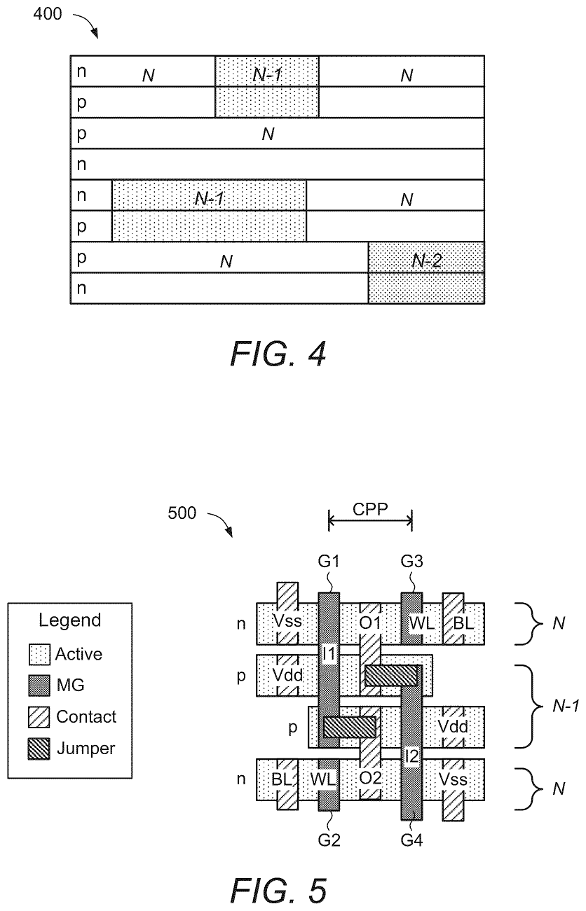

FIG. 4 is a is a plan view of a standard cell based circuit 400 that utilizes cells with different nanosheet counts, according to aspects of the disclosure. In the example illustrated in FIG. 4, most of the circuit 400 comprises standard cells with a nanosheet count of N, but some portions comprise standard cells with a nanosheet count of N−1, and one portion comprises standard cells with a nanosheet count of N−2. The portions having N−1 nanosheets will be subject to process steps that remove the bottom nanosheet, and the portions having N−2 nanosheets will be subject to process steps that remove the bottom two nanosheets. The same principles may be applied to remove the bottom three or more nanosheets during a backside nanosheet removal process.

FIG. 5 is a plan view of a static random access memory (SRAM) cell 500 that utilizes cells with different nanosheet counts, according to aspects of the disclosure. In the example shown in FIG. 5, the SRAM cell 500 includes n-doped and p-doped active regions, four gate structures labeled G1 through G4, and various S/D contacts and jumpers that configure the FETs into a first inverter (11) having a first output (01), cross-coupled to a second inverter (12) having a second output (02). Gates G2 and G3 are word lines (WLs), and some contacts are bit lines (BLs). In the example shown in FIG. 5, the n-type FETs (NFETs) of the inverters, which may also be called pull-down transistors, have a nanosheet count of N while the p-type FETs (PFETs) of the inverters, which may also be called pull-up transistors, have a nanosheet count of N−1. As a result, the PFETs of the inverters are weaker than the NFETs of the inverters. Selective strength adjustment of SRAM transistors may be used to optimize functionality metrics. For example, using N for pull-down (PD) and pass gate (PG) and N−1 for pullup (PU) can improve write margin, while using N for PD and N−1 for PG can improve static noise margin (SNM).

The techniques described herein provide a number of advantages. For example, the techniques to reduce the active number of nanosheets by backside removal described herein can be used for any type of circuit that uses gate-all-around FET topologies, including, but not limited to, digital logic circuitry, memory, or analog circuitry. As described above, this technique enables the creation of standard cell libraries having variations of logic gates with different numbers of nanosheets, and standard cells having a mix of nanosheet stack sizes within the same standard cell.

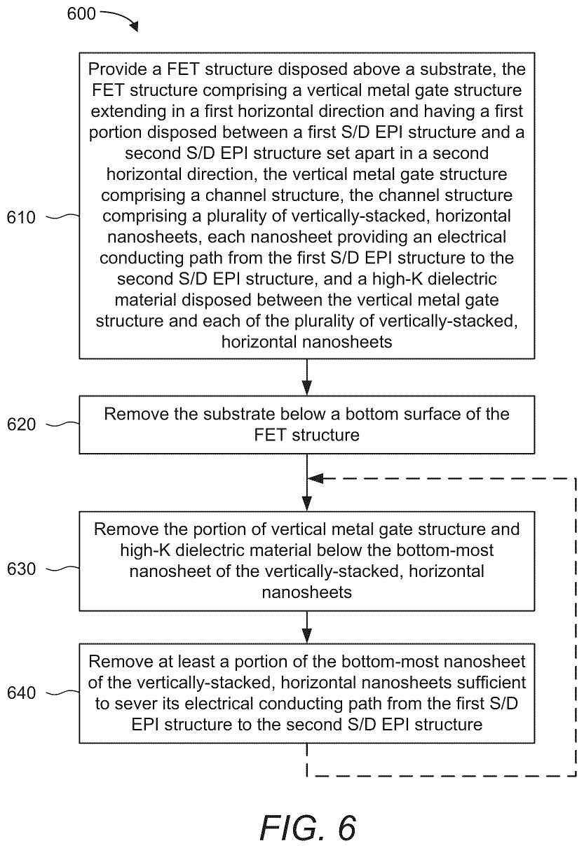

FIG. 6 is a flowchart of an example process 600 associated with a semiconductor structure with a reduced nanosheet count by backside nanosheet removal, according to aspects of the disclosure.

As shown in FIG. 6, process 600 may include, at block 610, providing a FET structure disposed above a substrate, the FET structure comprising a vertical metal gate structure extending in a first horizontal direction and being disposed between a first S/D EPI structure and a second S/D EPI structure set apart in a second horizontal direction, the vertical metal gate structure comprising a channel structure, the channel structure comprising a plurality of vertically-stacked, horizontal nanosheets, each nanosheet providing an electrical conducting path from the first S/D EPI structure to the second S/D EPI structure, and a gate dielectric material disposed between the vertical metal gate structure and each of the plurality of vertically-stacked, horizontal nanosheets.

As further shown in FIG. 6, process 600 may include, at block 620, removing the substrate below a bottom surface of the FET structure. In some aspects, this may be accomplished by substrate grind, CMP, and full removal process.

As further shown in FIG. 6, process 600 may include, at block 630, removing a portion of vertical metal gate structure and gate dielectric material below a bottom-most nanosheet of the vertically-stacked, horizontal nanosheets. In some aspects, this may be accomplished by using a first selective etch process to remove some or all of the bottom metal “finger” underneath the bottom nanosheet, and by using a second selective etch process to remove at least some of the gate dielectric material thus exposed by the first selective etch process. In some aspects, all of the bottom metal finger may be removed. In some aspects, all of the gate dielectric material on the bottom surface of the bottom-most nanosheet may be removed.

As further shown in FIG. 6, process 600 may include, at block 640, removing at least a portion of the bottom-most nanosheet of the vertically-stacked, horizontal nanosheets sufficient to sever its electrical conducting path from the first S/D EPI structure and the second S/D EPI structure. In some aspects, this may be accomplished by a third selective etch process that removes at least some of the bottom-most nanosheet by an etch process, i.e., enough to break the conducting path between the two S/D EPI structures by the nanosheet. In some aspects, some or all of the bottom-most nanosheet may be removed. At the conclusion of this step, the number of nanosheets N has been reduced by one, i.e., N−1.

As shown in FIG. 6, if more than one of the bottom-most nanosheets should be removed, then the process may repeat blocks 630 and 640 for each additional nanosheet to be removed, until the desired number of nanosheets has been removed, e.g., N−1 becomes N−2, and so on.

In some aspects, process 600 includes depositing dielectric material onto a bottom surface of the FET structure, e.g., to fill the recess caused by the etching steps above. In some aspects, process 600 also includes depositing dielectric material onto a bottom surface of the first S/D EPI structure and the second S/D EPI structure. This may be done by the same process or by a different process than the one that deposited the dielectric material onto the bottom surface of the FET structure.

In some aspects, process 600 includes creating a backside contact that extends vertically through the dielectric material to electrically couple to the first S/D EPI structure or the second S/D EPI structure. In some aspects, this involves a mask, etch, and metal deposition process.

In some aspects, process 600 includes forming, on a bottom surface of the substrate, a backside metal structure that is electrically coupled to the backside contact. In some aspects, at least a portion of the backside metal structure may comprise a backside power distribution network (BSPDN).

In some aspects, the vertical metal gate structure comprises a gate-all-around (GAA) structure.

Process 600 may include additional implementations, such as any single implementation or any combination of implementations described below and/or in connection with one or more other processes described elsewhere herein. Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

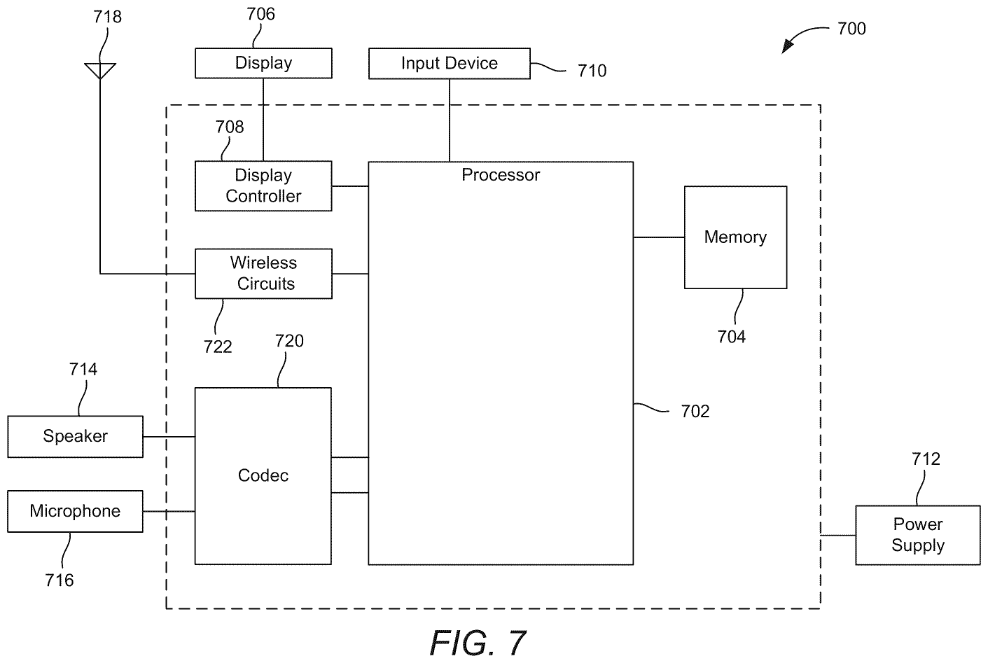

FIG. 7 illustrates a mobile device 700, according to aspects of the disclosure. In some aspects, the mobile device 700 may be implemented by including one or more IC devices manufactured based on the examples described in this disclosure.

In some aspects, mobile device 700 may be configured as a wireless communication device. As shown, mobile device 700 includes processor 702. Processor 702 may be communicatively coupled to memory 704 over a link, which may be a die-to-die or chip-to-chip link. Mobile device 700 also includes display 706 and display controller 708, with display controller 708 coupled to processor 702 and to display 706. The mobile device 700 may include input device 710 (e.g., physical, or virtual keyboard), power supply 712 (e.g., battery), speaker 714, microphone 716, and wireless antenna 718. In some aspects, the power supply 712 may directly or indirectly provide the supply voltage for operating some or all of the components of the mobile device 700.

In some aspects, FIG. 7 may include coder/decoder (CODEC) 720 (e.g., an audio and/or voice CODEC) coupled to processor 702; speaker 714 and microphone 716 coupled to CODEC 720; and wireless circuits 722 (which may include a modem, RF circuitry, filters, etc.) coupled to wireless antenna 718 and to processor 702.

In some aspects, one or more of processor 702, display controller 708, memory 704, CODEC 720, and wireless circuits 722 may include one or more IC devices including semiconductor structures manufactured according to the examples described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

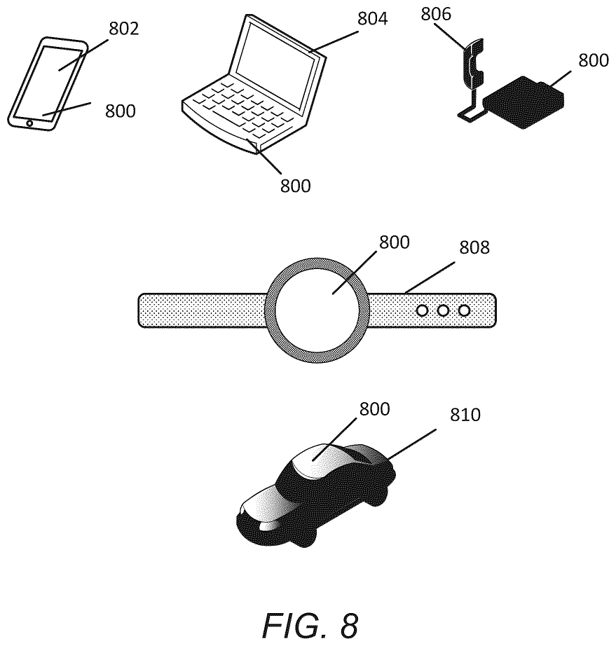

FIG. 8 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 802, a laptop computer device 804, a fixed location terminal device 806, a wearable device 808, or automotive vehicle 810 may include a semiconductor device 800 (e.g., semiconductor structure 200, the circuit 400, the SRAM cell 500) as described herein. The devices 802, 804, 806 and 808 and the vehicle 810 illustrated in FIG. 8 are merely exemplary. Other apparatuses or devices may also feature the semiconductor device 800 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A method of fabricating a semiconductor structure, the method comprising: providing a field effect transistor (FET) structure disposed above a substrate, the FET structure comprising a vertical metal gate structure extending in a first horizontal direction and being disposed between a first source/drain (S/D) epitaxial (EPI) structure and a second S/D EPI structure set apart in a second horizontal direction, the vertical metal gate structure comprising a channel structure, the channel structure comprising a plurality of vertically-stacked, horizontal nanosheets, each nanosheet providing an electrical conducting path from the first S/D EPI structure to the second S/D EPI structure, and a gate dielectric material disposed between the vertical metal gate structure and each of the plurality of vertically-stacked, horizontal nanosheets; removing the substrate below a bottom surface of the FET structure; removing a portion of vertical metal gate structure and gate dielectric material below a bottom-most nanosheet of the vertically-stacked, horizontal nanosheets; and removing at least a portion of the bottom-most nanosheet of the vertically-stacked, horizontal nanosheets sufficient to sever its electrical conducting path from the first S/D EPI structure and the second S/D EPI structure.

Clause 2. The method of clause 1, further comprising depositing dielectric material onto the bottom surface of the FET structure.

Clause 3. The method of clause 2, further comprising depositing dielectric material onto a bottom surface of the first S/D EPI structure and the second S/D EPI structure.

Clause 4. The method of clause 3, further comprising creating a backside contact that extends vertically through the dielectric material to electrically couple to the first S/D EPI structure or the second S/D EPI structure.

Clause 5. The method of clause 4, further comprising forming, on a bottom surface of the substrate, a backside metal structure that is electrically coupled to the backside contact.

Clause 6. The method of any of clauses 1 to 5, wherein the vertical metal gate structure comprises a gate-all-around (GAA) structure.

Clause 7. A semiconductor structure, comprising: a substrate; and at least one field effect transistor (FET) structure disposed above the substrate, each FET structure comprising: a vertical metal gate structure extending in a first horizontal direction and being disposed between a first source/drain (S/D) epitaxial (EPI) structure and a second S/D EPI structure set apart in a second horizontal direction, the vertical metal gate structure comprising a channel structure, the channel structure comprising a plurality of vertically-stacked, horizontal nanosheets; a gate dielectric material disposed between the vertical metal gate structure and each of the plurality of vertically-stacked, horizontal nanosheets; and a backside insulating layer disposed below the vertical metal gate structure, the first S/D EPI structure and the second S/D EPI structure, wherein at least some of the vertically-stacked, horizontal nanosheets farthest from the backside insulating layer provide an electrical conducting path between the first S/D EPI structure to the second S/D EPI structure in the second horizontal direction through the vertical metal gate structure, and wherein at least one of the vertically-stacked, horizontal nanosheets closest to the backside insulating layer does not provide an electrical conducting path between the first S/D EPI structure and the second S/D EPI structure.

Clause 8. The FET structure of clause 7, wherein each of the vertically-stacked, horizontal nanosheets that does not provide an electrical conducting path between the first S/D EPI structure and the second S/D EPI structure comprises a conducting portion and a non-conducting portion.

Clause 9. The FET structure of clause 8, wherein the non-conducting portion comprises the substrate.

Clause 10. The FET structure of any of clauses 7 to 9, wherein the substrate comprises a dielectric material.

Clause 11. The FET structure of any of clauses 7 to 10, further comprising a backside contact through the substrate to at least one of the first S/D EPI structure or the second S/D EPI structure.

Clause 12. The FET structure of clause 11, wherein the backside contact is coupled to a backside metal structure disposed on a bottom surface of the substrate.

Clause 13. The FET structure of any of clauses 7 to 12, wherein the vertical metal gate structure comprises a gate-all-around (GAA) structure.

Clause 14. A semiconductor structure, comprising: a plurality of field effect transistor (FET) structures extending in a first horizontal direction and set apart in a second horizontal direction, wherein each FET structure comprises: a vertical metal gate structure extending in the first horizontal direction and being disposed between a first source/drain (S/D) epitaxial (EPI) structure and a second S/D EPI structure set apart in the second horizontal direction, the vertical metal gate structure comprising a channel structure, the channel structure comprising a plurality of vertically-stacked, horizontal nanosheets; a gate dielectric material disposed between the vertical metal gate structure and each of the plurality of vertically-stacked, horizontal nanosheets, at least one frontside dielectric layer disposed above the plurality of FET structures; and a backside insulating structure disposed below the plurality of FET structures, wherein for a first FET structure of the plurality of FET structures, the plurality of vertically-stacked, horizontal nanosheets comprises N nanosheets and for a second FET structure of the plurality of FET structures, the plurality of vertically-stacked, horizontal nanosheets comprises N−1 nanosheets having vertical positions that correspond with the N−1 nanosheets of the first FET structure that are closest to the at least one frontside dielectric layer.

Clause 15. The FET structure of clause 14, wherein the backside insulating structure comprises at least one dielectric layer.

Clause 16. The FET structure of clause 15, further comprising a backside contact through the backside insulating structure to at least one of the first S/D EPI structure or the second S/D EPI structure of the first FET structure or the second FET structure.

Clause 17. The FET structure of clause 16, wherein the backside contact is coupled to a backside metal structure disposed on a bottom surface of the backside insulating structure.

Clause 18. The FET structure of any of clauses 14 to 17, wherein each FET structure of the plurality of FET structures comprises a gate-all-around (GAA) structure.

Clause 19. A semiconductor structure, comprising: a plurality of field effect transistor (FET) structures, each FET structure comprising a vertical metal gate structure extending in a first horizontal direction and having a first portion disposed between a first source/drain (S/D) epitaxial (EPI) structure and a second S/D EPI structure set apart in a second horizontal direction, the vertical metal gate structure comprising a channel structure, the channel structure comprising a plurality of vertically-stacked, horizontal nanosheets, wherein for a first subset of the plurality of FET structures, the plurality of vertically-stacked, horizontal nanosheets comprises N nanosheets, and for a second subset of the plurality of FET structures, the plurality of vertically-stacked, horizontal nanosheets comprises N−1 nanosheets, wherein the bottom-most nanosheet of FET structures in the first subset of the plurality of FET structures is below the bottom-most nanosheet of FET structures in the second subset of the plurality of FET structures.

Clause 20. The semiconductor structure of clause 19, wherein the first subset of the plurality of FET structures comprise a first standard cell and the second subset of the plurality of FET structures comprise a second standard cell.

Clause 21. The semiconductor structure of any of clauses 19 to 20, wherein the first subset of the plurality of FET structures comprise a first portion of a standard cell and the second subset of the plurality of FET structures comprise a second portion of the standard cell.

Clause 22. The semiconductor structure of clause 21, wherein the standard cell comprises a static random access memory (SRAM) standard cell, a digital logic standard cell, or an analog standard cell.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., a user equipment (UE)). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A method of fabricating a semiconductor structure, the method comprising:
providing a field effect transistor (FET) structure disposed above a substrate, the FET structure comprising a vertical metal gate structure extending in a first horizontal direction and being disposed between a first source/drain (S/D) epitaxial (EPI) structure and a second S/D EPI structure set apart in a second horizontal direction, the vertical metal gate structure comprising a channel structure, the channel structure comprising a plurality of vertically-stacked, horizontal nanosheets, each nanosheet providing an electrical conducting path from the first S/D EPI structure to the second S/D EPI structure, and a gate dielectric material disposed between the vertical metal gate structure and each of the plurality of vertically-stacked, horizontal nanosheets;
removing the substrate below a bottom surface of the FET structure;
removing a portion of vertical metal gate structure and gate dielectric material below a bottom-most nanosheet of the vertically-stacked, horizontal nanosheets; and
removing at least a portion of the bottom-most nanosheet of the vertically-stacked, horizontal nanosheets sufficient to sever its electrical conducting path from the first S/D EPI structure and the second S/D EPI structure.

2. The method of claim 1, further comprising depositing dielectric material onto the bottom surface of the FET structure.

3. The method of claim 2, further comprising depositing dielectric material onto a bottom surface of the first S/D EPI structure and the second S/D EPI structure.

4. The method of claim 3, further comprising creating a backside contact that extends vertically through the dielectric material to electrically couple to the first S/D EPI structure or the second S/D EPI structure.

5. The method of claim 4, further comprising forming, on a bottom surface of the substrate, a backside metal structure that is electrically coupled to the backside contact.

6. The method of claim 1, wherein the vertical metal gate structure comprises a gate-all-around (GAA) structure.

7. A semiconductor structure, comprising:
a substrate; and
at least one field effect transistor (FET) structure disposed above the substrate, each FET structure comprising:
a vertical metal gate structure extending in a first horizontal direction and being disposed between a first source/drain (S/D) epitaxial (EPI) structure and a second S/D EPI structure set apart in a second horizontal direction, the vertical metal gate structure comprising a channel structure, the channel structure comprising a plurality of vertically-stacked, horizontal nanosheets;
a gate dielectric material disposed between the vertical metal gate structure and each of the plurality of vertically-stacked, horizontal nanosheets; and
a backside insulating layer disposed below the vertical metal gate structure, the first S/D EPI structure and the second S/D EPI structure,
wherein at least some of the vertically-stacked, horizontal nanosheets farthest from the backside insulating layer provide an electrical conducting path between the first S/D EPI structure to the second S/D EPI structure in the second horizontal direction through the vertical metal gate structure, and wherein at least one of the vertically-stacked, horizontal nanosheets closest to the backside insulating layer does not provide an electrical conducting path between the first S/D EPI structure and the second S/D EPI structure.

8. The FET structure of claim 7, wherein each of the vertically-stacked, horizontal nanosheets that does not provide an electrical conducting path between the first S/D EPI structure and the second S/D EPI structure comprises a conducting portion and a non-conducting portion.

9. The FET structure of claim 8, wherein the non-conducting portion comprises the substrate.

10. The FET structure of claim 7, wherein the substrate comprises a dielectric material.

11. The FET structure of claim 7, further comprising a backside contact through the substrate to at least one of the first S/D EPI structure or the second S/D EPI structure.

12. The FET structure of claim 11, wherein the backside contact is coupled to a backside metal structure disposed on a bottom surface of the substrate.

13. The FET structure of claim 7, wherein the vertical metal gate structure comprises a gate-all-around (GAA) structure.

14. A semiconductor structure, comprising:
a plurality of field effect transistor (FET) structures extending in a first horizontal direction and set apart in a second horizontal direction, wherein each FET structure comprises:
a vertical metal gate structure extending in the first horizontal direction and being disposed between a first source/drain (S/D) epitaxial (EPI) structure and a second S/D EPI structure set apart in the second horizontal direction, the vertical metal gate structure comprising a channel structure, the channel structure comprising a plurality of vertically-stacked, horizontal nanosheets;
a gate dielectric material disposed between the vertical metal gate structure and each of the plurality of vertically-stacked, horizontal nanosheets,
at least one frontside dielectric layer disposed above the plurality of FET structures; and
a backside insulating structure disposed below the plurality of FET structures,
wherein for a first FET structure of the plurality of FET structures, the plurality of vertically-stacked, horizontal nanosheets comprises N nanosheets and for a second FET structure of the plurality of FET structures, the plurality of vertically-stacked, horizontal nanosheets comprises N−1 nanosheets having vertical positions that correspond with the N−1 nanosheets of the first FET structure that are closest to the at least one frontside dielectric layer.

15. The FET structure of claim 14, wherein the backside insulating structure comprises at least one dielectric layer.

16. The FET structure of claim 15, further comprising a backside contact through the backside insulating structure to at least one of the first S/D EPI structure or the second S/D EPI structure of the first FET structure or the second FET structure.

17. The FET structure of claim 16, wherein the backside contact is coupled to a backside metal structure disposed on a bottom surface of the backside insulating structure.

18. The FET structure of claim 14, wherein each FET structure of the plurality of FET structures comprises a gate-all-around (GAA) structure.

19. A semiconductor structure, comprising:
a plurality of field effect transistor (FET) structures, each FET structure comprising a vertical metal gate structure extending in a first horizontal direction and having a first portion disposed between a first source/drain (S/D) epitaxial (EPI) structure and a second S/D EPI structure set apart in a second horizontal direction, the vertical metal gate structure comprising a channel structure, the channel structure comprising a plurality of vertically-stacked, horizontal nanosheets,
wherein for a first subset of the plurality of FET structures, the plurality of vertically-stacked, horizontal nanosheets comprises N nanosheets, and for a second subset of the plurality of FET structures, the plurality of vertically-stacked, horizontal nanosheets comprises N−1 nanosheets, wherein the bottom-most nanosheet of FET structures in the first subset of the plurality of FET structures is below the bottom-most nanosheet of FET structures in the second subset of the plurality of FET structures.

20. The semiconductor structure of claim 19, wherein the first subset of the plurality of FET structures comprise a first standard cell and the second subset of the plurality of FET structures comprise a second standard cell.

21. The semiconductor structure of claim 19, wherein the first subset of the plurality of FET structures comprise a first portion of a standard cell and the second subset of the plurality of FET structures comprise a second portion of the standard cell.

22. The semiconductor structure of claim 21, wherein the standard cell comprises a static random access memory (SRAM) standard cell, a digital logic standard cell, or an analog standard cell.
